(19) United States
(12) Patent Application Publication
(10) Pub. No.: US 2009/0274322 A1
(43) Pub. Date: Nov. 5, 2009

(54) Volume Control Apparatus and Method

(75) Inventors: Jung-Kuei Chang, Hsinchu Hsien (TW); Huang-Hsiang Lin, Hsinchu Hsien (TW); Shao-Shi Chen, Hsinchu Hsien (TW)

Correspondence Address: WPAT, PC, 7225 BEVERLY ST., ANNANDALE, VA, 22003, US

(73) Assignee: MSTAR SEMICONDUCTOR, INC., Hsinchu Hsien (TW)

(21) Appl. No.: 12/435,621

(22) Filed: May 5, 2009

Related U.S. Application Data
(60) Provisional application No. 61/050,292, filed on May 5, 2008.

(51) Int. Cl. H03G 3/00; H03G 3/20

(52) U.S. Cl. 381/107; 381/57

(57) ABSTRACT

A volume control apparatus and method is provided. The volume control apparatus includes an automatic gain controller and an equal loudness controller. The method includes steps of receiving an original sound signal by the automatic gain controller, adjusting the original sound signal by the automatic gain controller according to a target volume to output an auto-gain sound signal that gradually converges to the target volume, and rendering a loudness curve according to the target volume for compensating the auto-gain sound signal to output a compensated sound signal.

### CROSS REFERENCE TO RELATED PATENT APPLICATION

This patent application benefits from a U.S. provisional patent application No. 61/050,292 filed May 5, 2008.

### FIELD OF THE INVENTION

The present invention relates to a volume control apparatus and method, and more particularly, to a volume control apparatus and method applied to a television controller.

### BACKGROUND OF THE INVENTION

When switching between channels, signal sources (e.g., from analog television to digital television), or between a program and commercials, a viewer may find abrupt volume variations resulted from video content changes rather disturbing. For example, from a program to commercials, the volume usually gets larger, and the viewer often needs to adjust the volume using a remote control.

To improve the above issue, various smart volume control mechanisms with complex circuits, for automatically monitoring the volume of a television have been developed, to eliminate disturbances caused by abrupt volume variations and troubles from adjusting the volume manually. However, inappropriate suppression on volume variations may lead to a certain degree of deterioration in sound quality and dynamic response capability. Therefore, it is a goal of the television controller manufacturers to retain sound quality and dynamic responses while overcoming the above issue.

### SUMMARY OF THE INVENTION

The present invention discloses a volume control apparatus for adjusting an original sound signal to a target volume. The volume control apparatus comprises: an automatic gain controller, for adjusting the received original sound signal to output an auto-gain sound signal that gradually converges to the target volume; and an equal loudness controller, coupled to the automatic gain controller, for rendering a loudness curve according to the target volume to compensate the auto-gain sound signal to output a compensated sound signal.

According to the volume control apparatus of the invention, the equal loudness controller renders a plurality of loudness curves corresponding to different target volumes; and the gain of the loudness curves within a predetermined frequency range is substantially the same while the gain outside the predetermined frequency range is higher.

According to the volume control apparatus of the invention, the equal loudness controller is a programmable bi-quadratic impulse response filter, which selects the loudness curve among the plurality of loudness curves having different characteristics by setting parameters of the programmable bi-quadratic impulse response filter.

According to the volume control apparatus of the invention, the automatic gain controller comprises: a multiplier, for multiplying the original sound signal with a gain to output the auto-gain sound signal to the equal loudness controller; a level detector, coupled to the multiplier, for detecting the level of the outputted auto-gain sound signal to output a sound level; a target volume comparator, coupled to the level detector, for subtracting the sound level from the target volume to obtain a first difference; and a gain generator, coupled to the target volume comparator and the multiplier, for generating the gain, and adjusting the gain according to the first difference

According to the volume control apparatus of the invention, the automatic gain controller comprises: a multiplier, coupled to the target volume comparator, for multiplying the first difference outputted from the target volume comparator with the gain to obtain a first product; a first sign detector, coupled to the multiplier, for sending a selection signal in response to a positive/negative sign of the first product; a gain timing controller, coupled to the first sign detector, for selecting a corresponding increment curve in response to the selection signal to generate an increase; and an adder, coupled to the gain timing controller and the multiplier, for incrementing the gain; and a decibel/scalar converter, for converting a unit of the gain into a scalar and outputting the gain in the scalar to the multiplier.

According to the volume control apparatus of the invention, the gain generator further comprises a limiter, which is coupled between the adder and the decibel/scalar converter and is for limiting the gain under a predetermined maximum value.

According to the volume control apparatus of the invention, the automatic gain controller comprises: a multiplier, for adjusting the original sound signal according to a gain to output the auto-gain sound signal to the equal loudness controller; a level detector, coupled to the multiplier, for detecting the level of the outputted auto-gain sound signal to output a sound level; a target volume comparator, coupled to the level detector, for subtracting the sound level from the target volume to obtain a first difference; a gain generator, coupled to the target volume comparator and the multiplier, for generating the gain, and adjusting the gain according to the first difference; and a noise detector, coupled to the level detector and the gain generator, for subtracting a noise level and the gain from the sound level outputted from the level detector to obtain a second difference; wherein, the gain outputted from the gain generator is reset to zero when the second difference stays negative for a predetermined time period.

According to the volume control apparatus of the invention, the gain generator comprises: a multiplexer, coupled to the noise detector and the target volume comparator, controlled by the noise detector to output either the first difference or a reciprocal of the gain; a multiplier, coupled to the multiplexer, for multiplying the output from the multiplexer with the gain to obtain a first product; a first sign detector, coupled to the multiplier, for sending a selection signal in response to a positive/negative sign of the first product; a gain timing controller, coupled to the first sign detector, for selecting a corresponding increment curve in response to the selection signal to generate an increase; an adder, coupled to the gain timing controller and the multiplier, for incrementing the gain; and a decibel/scalar converter, for converting a unit of the gain into a scalar and outputting the gain in the scalar to the multiplier.

According to the volume control apparatus of the invention, the gain generator further comprises a limiter, which is coupled between the adder and the decibel/scalar converter and is for limiting the gain under a predetermined maximum value.

According to the volume control apparatus of the invention, the level detector comprises: a high-pass filter, coupled to the multiplier, for removing DC components and bass from the auto-gain sound signal; an absolute value unit, coupled to the high-pass filter, for converting negative components of an AC signal in the auto-gain sound signal to positive components; a low-pass filter, coupled to the absolute value unit, for obtaining the sound level associated with an energy average value of the auto-gain sound signal; and a decibel converter, coupled to the low-pass filter and the target volume comparator, for converting the sound level into a unit of decibels using a look-up table and outputting the sound level in decibels to the target volume comparator.

According to the volume control apparatus of the invention, the automatic gain controller comprises: a programmable delay, for delaying the original sound signal with a predetermined delay; a multiplier, coupled to the programmable delay, for adjusting the original sound signal having been delayed by the predetermined delay according to a gain to output an auto-gain sound signal to the equal loudness controller; a level detector, coupled to the multiplier, for detecting the level of the outputted auto-gain sound signal to output a sound level; a target volume comparator, coupled to the level detector, for subtracting the sound level from the target volume to obtain a first difference; and a gain generator, coupled to the target volume comparator and the multiplier, for generating the gain, and adjusting the gain according to the first difference.

According to the volume control apparatus of the invention, the automatic gain controller comprises: a programmable delay, for delaying the original sound signal with a predetermined delay; a multiplier, coupled to the programmable delay, for adjusting the original sound signal having been delayed by the predetermined delay according to a gain to output an auto-gain sound signal to the equal loudness controller; a level detector, coupled to the multiplier, for detecting the level of the outputted auto-gain sound signal to output a sound level; a target volume comparator, coupled to the level detector, for subtracting the sound level from the target volume to obtain a first difference; a gain generator, coupled to the target volume comparator and the multiplier, for generating the gain, and adjusting the gain according to the first difference; and a noise detector, coupled to the level detector and the gain generator, for subtracting a noise level and the gain from the sound level outputted from the level detector to obtain a second difference; wherein, the gain outputted from the gain generator is reset to zero when the second difference stays negative for a predetermined time period.

The present invention further discloses a volume control method for adjusting an original sound signal to a target volume. The volume control method comprises steps of receiving an original sound signal, adjusting the original sound signal according to the target volume to gradually converge the original sound signal to an auto-gain sound signal at the target volume, and rendering a loudness curve according to the target volume to compensate the auto-gain sound signal to output a compensated sound signal.

According to the volume control method of the invention, the loudness curve is rendered from a plurality of loudness curves corresponding to the target volume at different levels; and the gain of the loudness curves within a predetermined frequency range is substantially the same, while the gain outside the predetermined frequency range is higher.

According to the volume control method of the invention, the step of adjusting the original sound signal according to the target volume comprises steps of adjusting the original sound signal according to a gain to output the auto-gain sound signal, detecting the level of the auto-gain sound signal to output a sound level, subtracting the sound level from the target volume to obtain a first difference, and adjusting the gain according to the first difference.

According to the volume control method of the invention, the step of adjusting the gain according to the first difference comprises steps of multiplying the first difference with the gain to obtain a first product, sending a selection signal in response to a positive/negative sign of the first product, selecting a corresponding increment curve in response to the selection signal to generate an increase, and incrementing the gain.

According to the volume control method of the invention, the incrementing the incremented gain is limited under a maximum value.

According to the volume control method of the invention, the step of adjusting the original sound signal according to the target volume comprises steps of adjusting the original sound signal according to a gain to output the auto-gain sound signal, detecting the level of the auto-gain sound signal to output a sound level, subtracting the sound level from the target volume to obtain a first difference, adjusting the gain according to the first difference, and subtracting a noise level and the gain from the sound level to obtain a second difference; wherein, the gain is reset to zero when the second difference stays negative for a predetermined time period.

According to the volume control method of the invention, the step of adjusting the outputted gain according to the first difference comprises steps of outputting either the first difference or a reciprocal of the gain in response to changes in the second difference, multiplying either the first difference or a reciprocal of the gain with the gain to obtain a first product, sending a selection signal in response to a positive/negative sign of the first product, selecting a corresponding increment curve in response to the selection signal to generate an increase, and incrementing the gain.

According to the volume control method of the invention, the incremented gain is limited under a maximum value.

According to the volume control method of the invention, the step of detecting the level of the auto-gain sound signal to output a sound level comprises steps of removing DC components and bass from the auto-gain sound signal, converting negative components of an AC signal in the auto-gain sound signal to positive components, obtaining the sound level associated with an energy average value of the auto-gain sound signal, and converting the sound level into a unit of decibels using a look-up table and outputting the sound level in decibels.

According to the volume control method of the invention, the step of adjusting the outputted gain according to the first difference further comprises a step of converting the gain into a scalar and outputting the scalar.

According to the volume control method of the invention, the step of adjusting the original sound signal according to the target volume comprises steps of delaying the original sound signal by a predetermined delay, adjusting the original sound signal according to the target volume having been delayed by the predetermined delay according to a gain to output the auto-gain sound signal, subtracting the sound level from the target volume to obtain a first difference, and adjusting the gain according to the first difference.

According to the volume control method of the invention, the step of adjusting the original sound signal according to the target volume comprises steps of delaying the original sound signal by a predetermined delay, adjusting the original sound signal according to the target volume having been delayed by the predetermined delay according to a gain to output the auto-gain sound signal, subtracting the sound level from the target volume to obtain a first difference, adjusting the gain according to the first difference, and subtracting a noise level and the gain from the sound level to obtain a second difference; wherein, the gain is reset to zero when the second difference stays negative for a predetermined time period.

### BRIEF DESCRIPTION OF THE DRAWINGS

The present invention will become more readily apparent to those ordinarily skilled in the art after reviewing the following detailed description and accompanying drawings, in which:

FIG. 1 is a functional block diagram of a smart volume control apparatus according to one embodiment of the invention.

FIG. 2a is a schematic diagram of a plurality of loudness curves in an equal loudness controller.

FIG. 2b is a circuit schematic diagram of the equal loudness controller 11 according to one embodiment of the invention.

FIG. 3a is a circuit block diagram of an automatic gain controller (AGC) according to a first embodiment of the invention.

FIG. 3b is a circuit block diagram of an AGC according to a second embodiment of the invention.

FIG. 3c is a circuit block diagram of an AGC according to a third embodiment of the invention.

FIG. 3d is a circuit block diagram of an AGC according to a fourth embodiment of the invention.

FIGS. 4a and 4c show detailed block diagrams of a gain generator.

FIGS. 4b and 4d show detailed block diagrams of a gain generator and a noise detector.

FIGS. 5a and 5b respectively show a detailed block diagram and a schematic diagram of frequency response of the level detector.

FIG. 6 is a waveform schematic diagram of the gain A, the original sound signal and the auto-gain sound signal when operating the apparatus according to one embodiment of the invention.

FIG. 7 is a waveform schematic diagram of the gain A and the original sound signal upon detecting a noise when operating the apparatus according one embodiment of the invention.

FIG. 8 is a flowchart of a volume control method according to one embodiment of the invention.

FIG. 9 is a detailed flowchart illustrating Step 82 of the invention.

FIG. 10 is another detailed flowchart illustrating Step 82 of the invention.

### DETAILED DESCRIPTION OF THE PREFERRED EMBODIMENT

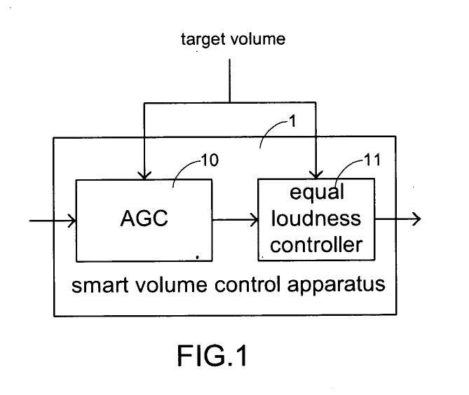

Refer to FIG. 1 showing a block diagram of a smart volume control apparatus 1 according to one embodiment of the invention. An automatic gain control (AGC) 10 receives an original sound signal, and, by reducing or amplifying the energy or waveform amplitude, adjusts the original sound signal according to a gain. The gain applied to the original sound signal, reflecting changes of the original sound signal, also varies along with time, to further calibrate the volume of the auto-gain sound signal. The volume is gradually converged to a predetermined target volume, whereby disturbances caused by abrupt volume variations when switching between channels or switching from a program to commercials are eliminated. In this embodiment, an output end of the AGC 10 is connected with an equal loudness controller 11 that renders different loudness curves according to different target volume. The different loudness curves are applied to compensate and fine-tune the auto-gain sound signal to output a compensated sound signal.

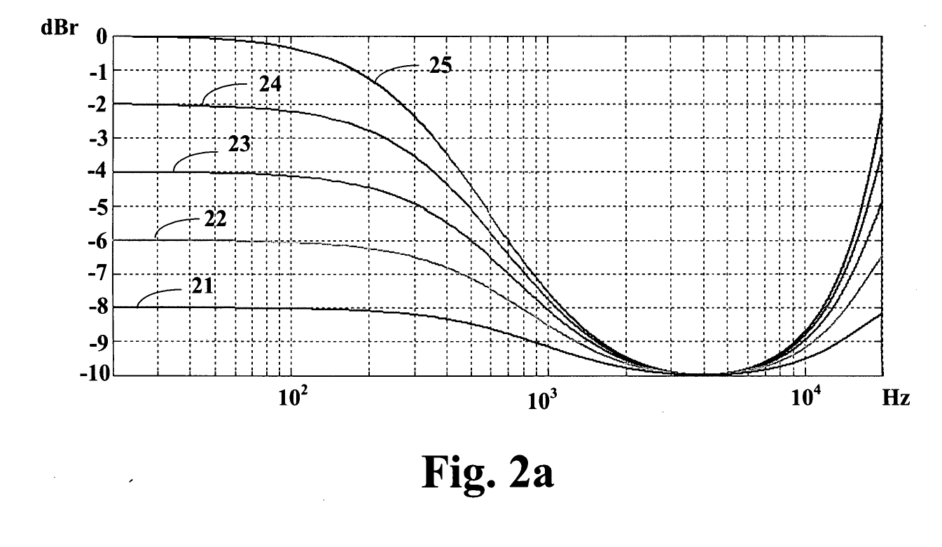

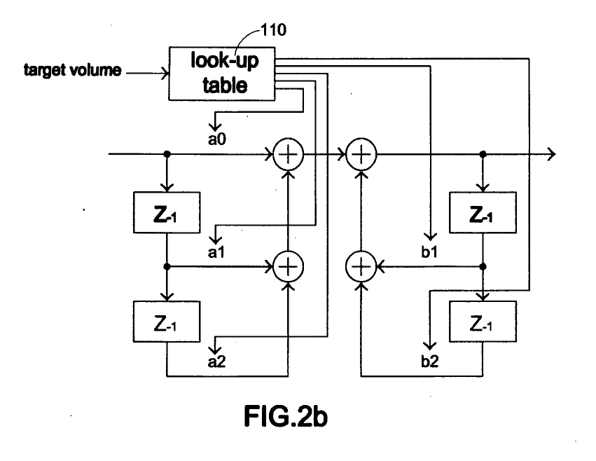

Based on settings of different target volumes, the equal loudness controller 11 provides a plurality of loudness curves as shown in FIG. 2a for fine-tuning the auto-gain sound signal outputted from the AGC 10. For example, the four curves represent loudness curves map to different target volumes. The horizontal axis represents the sound frequency, and the vertical axis represents the corresponding gain in dBr. It is observed that, within the frequency range around 3˜4 KHz that is sensitive to the human ear, the gain of the four curves is controlled at −10 dBr. At high frequency bands and low frequency bands outside the 3˜4 KHz range, the gain increases by different values. The human ear is less sensitive at the high and low frequency bands, and the high and low frequencies shall sound indistinct and even diminishing if all frequency bands are amplified by one same scale. Therefore, the equal loudness controller 11 compensates the intensity of the high and low frequency bands according to the loudness curves in FIG. 2a. Further, when the target volume gets smaller, compensation intensity at the high and low frequency bands at the two ends of the 3˜4 KHz range gets larger. For example, supposing the target volume is divided into levels 1 to 5 from high to low, four loudness curves 21 to 25 are as shown in FIG. 2a. Therefore, even if the target volume of the AGC 10 is set at a very low level, high-frequency and low-frequency sounds are still presented clearly.

Refer to FIG. 2b showing a circuit schematic diagram of the equal loudness controller 11 according to one embodiment of the invention. The equal loudness controller 11 is a programmable bi-quadratic infinite impulse response filter, of which the Z transfer function is H(Z)=(a0+a1*Z⁻¹+a2*Z⁻²)/(1−b1*Z⁻¹−b2*Z⁻²). By programming settings of parameters a0, a1, b1, and b2, the loudness curves 21, 22, 23, 24 and 25 in FIG. 2a are produced respectively. A look-up table 110 is provided in the equal loudness controller 11, in which relationships between the target volume in level 1, level 2, level 3, level 4 and level 5, and the parameters a0, a1, a2, b1 and b2 are established. Accordingly, the equal loudness controller 11 may operate based on the curves 21 to 25 to produce the compensated sound signal with better quality to be outputted to a subsequent device. The foregoing original sound signal, auto-gain sound signal, and compensated sound signal may be common pulse-code modulation (PCM) sound signals, or may be sound signals in other digital coding algorithms. The compensated sound signal is forwarded to a subsequent corresponding digital-to-analog converter (DAC) for further processing. In light of the above disclosure, for a person having ordinary skill in the art, the invention can be realized by implementing an infinite impulse response filter or a finite impulse response filter.

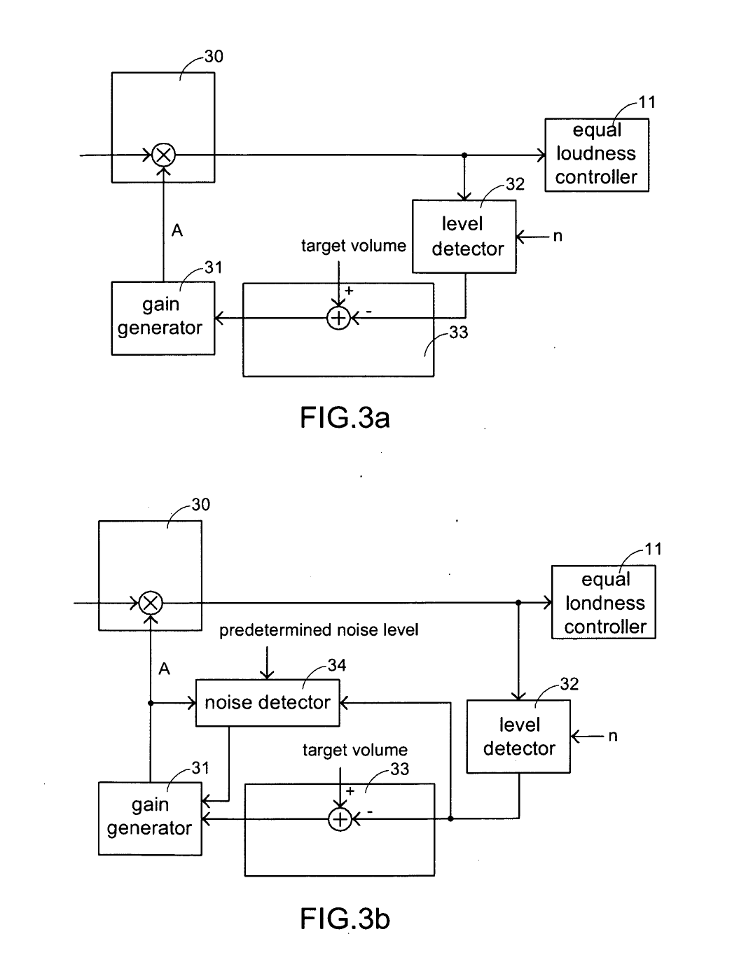

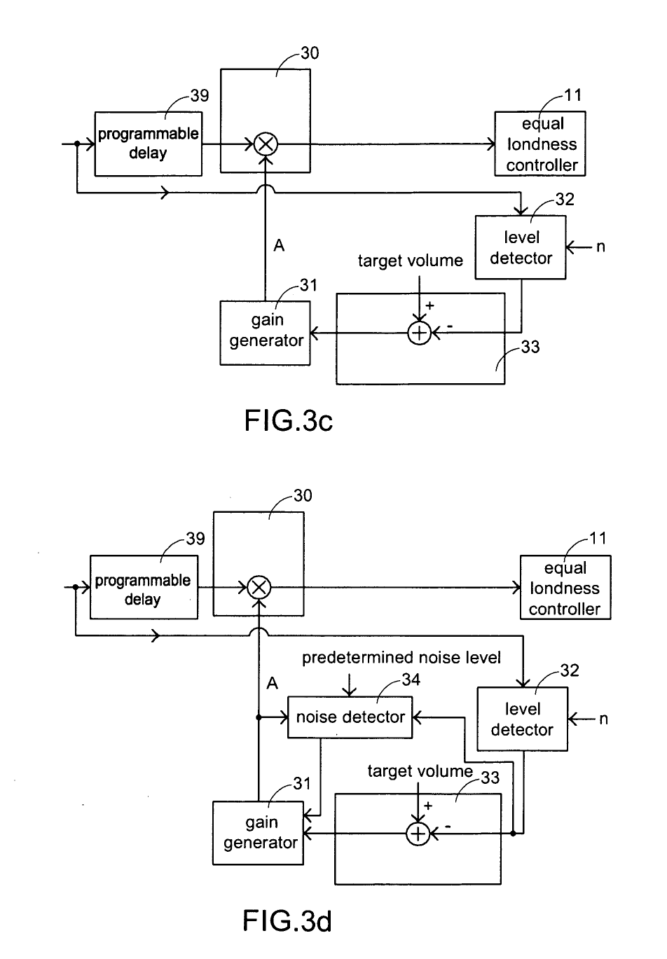

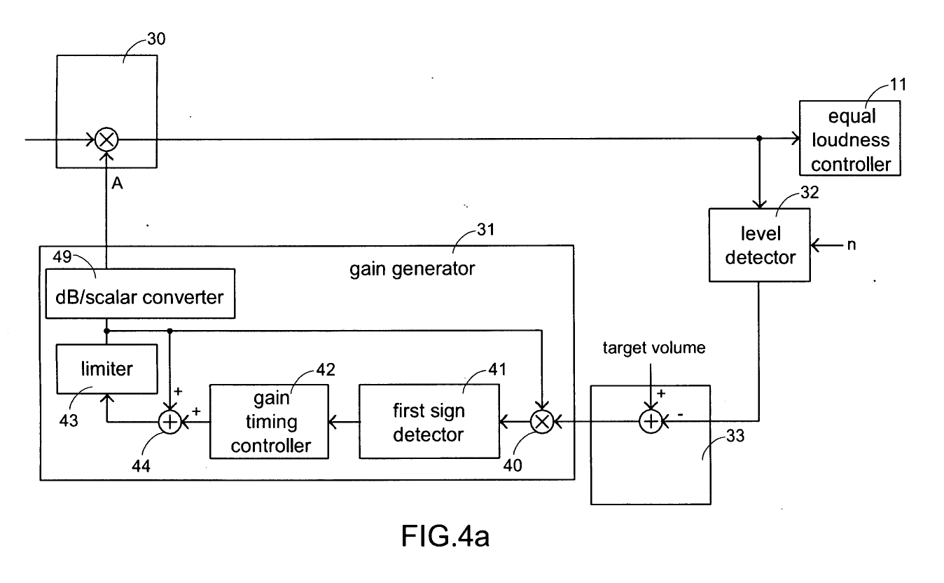

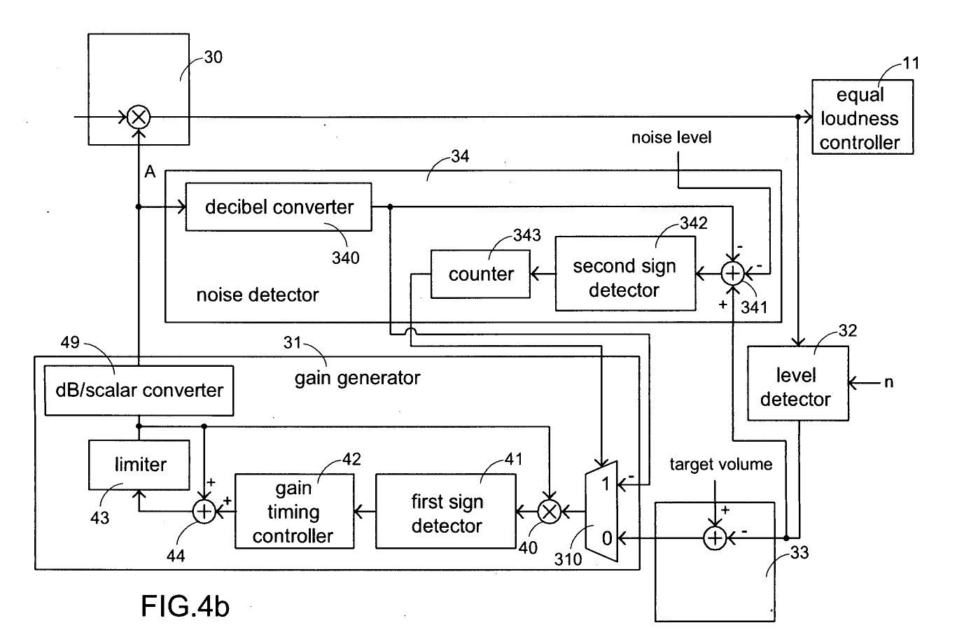

Refer to FIG. 3a showing a circuit block diagram of the AGC 10 according to a first embodiment of the invention. The original sound signal is sent to a multiplier 30, which adjusts the original sound signal according to a gain A outputted from a gain generator 31. The original sound signal is then outputted as the auto-gain sound signal to the equal loudness controller 11. In order to facilitate the gain A to vary with time as reflecting changes in the original sound signal, a level detector 32 is provided according to one embodiment of the invention. The level detector 32 detects the level of the outputted auto-gain sound signal to output a sound level to a target volume comparator 33. Preferably, the sound level is measured in dB to reflect characteristics of how the human ear reacts to sound intensity. The target volume comparator 33 subtracts the sound level from the target volume to obtain a first difference that is then sent to the gain generator 31. The gain generator 31, according to the first difference, increases or decreases the outputted gain A to match the level of the auto-gain sound signal with the target volume.

FIG. 3b shows a circuit block diagram of the AGC 10 according to a second embodiment of the invention. The main difference between the second embodiment and the first embodiment shown in FIG. 3a is that, in the second embodiment, a noise detector 34 is provided. The noise detector 34, according to a predetermined noise level and a predetermined time period, subtracts the noise level and the gain A from the sound level outputted from the level detector 32 to obtain a second difference, of which a positive/negative sign is capable of indicating whether only a noise, but no normal signal, is present. In the event that the second difference stays negative for the predetermined time period, the first difference sent to the gain generator 31 is replaced by the gain A to stop the gain generator 31 from amplifying the signal determined as a noise, i.e., to prevent the noise from being erroneously amplified to the target volume.

FIG. 3c and FIG. 3d show circuit block diagrams of the AGC 10 according to third and fourth embodiments of the invention. The third embodiment shown in FIG. 3c, modified from the first embodiment shown in FIG. 3a, is additionally provided with a programmable delay 39. The programmable delay 39 delays with a predetermined delay before feeding the original sound signal into the multiplier 30. The predetermined delay is determined based on the time needed by the original sound signal to enter the level detector 32, the target volume comparator 33 and the gain generator 31 to generate the gain A, such that the gain A from the gain generator 31 is allowed to adjust the original sound signal at a correct timing point. Similarly, the fourth embodiment shown in FIG. 3d, modified from the second embodiment shown in FIG. 3b, is also additionally provided with a programmable delay 39. The programmable delay 39 delays with a predetermined delay before feeding the original sound signal into the multiplier 30. The predetermined delay is determined based on the time needed by the original sound signal to enter the level detector 32, the target volume comparator 33, the gain generator 31 and the noise comparator 34 to generate the gain A, such that the gain A from the gain generator 31 is allowed to adjust the original sound signal at a precise timing point.

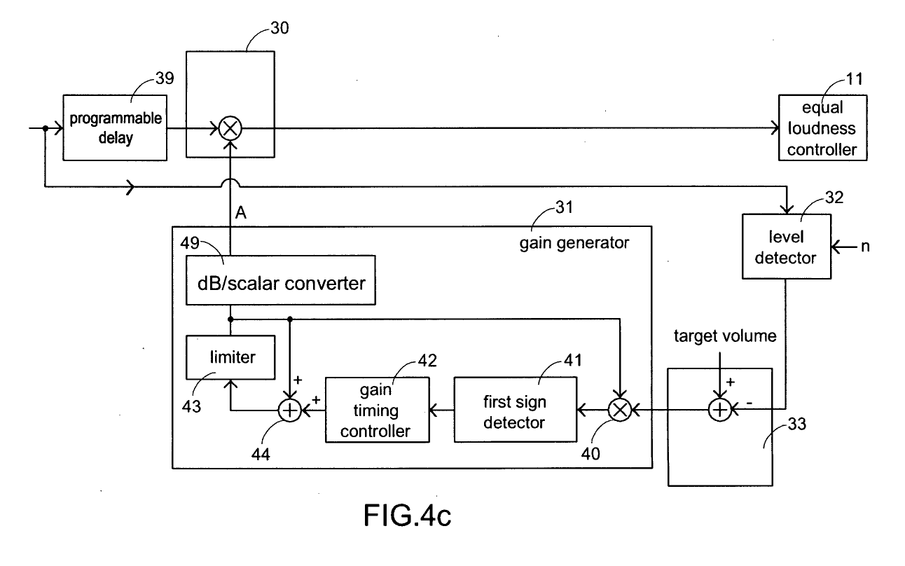

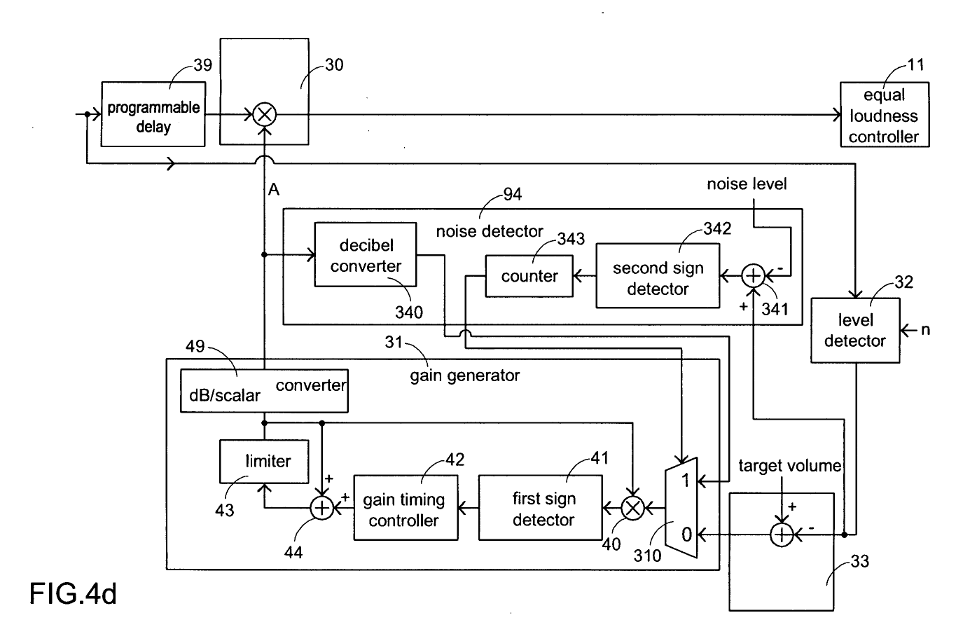

FIG. 4a a shows a detailed block diagram of the gain generator 31 in FIG. 3a. The first difference outputted from the comparator 33 and the outputted gain A are multiplied using a multiplier 40 to obtain a first product. The first product is fed to a first sign detector 41, which then operates and sends a selection signal to a gain timing controller 42. When the first product is positive, it means that the outputted auto-gain sound signal is smaller than the target volume. At this point, an increment curve in the gain timing controller 42 is applied to generate an increment, which is then added to the feedback gain A using an adder 44 to generate a new gain A, so as to gradually increase the gain A to match the level of the auto-gain sound signal with the target volume. Conversely, when the first product is negative, it means that the outputted auto-gain sound signal is larger than the target volume. At this point, a decrement curve in the gain timing controller 42 is applied to generate a decrement, which is then added to a feedback gain A to output an updated gain A, so as to gradually decrease the gain A to match the level of the auto-gain sound signal with the target volume. A limiter 43 is implemented to limit the maximum value of the gain A to prevent system instability. The gain generator 31, having a decibel/scalar converter 49, converts the gain outputted from the limiter 43 from a decibel into a scalar to be applied to the multiplier 30.

FIG. 4b further shows a detailed block diagram of the gain generator 31 and the noise detector 34 in FIG. 3b. The noise detector 34 comprises a decibel converter 340 for converting the unit of the gain A into decibels, e.g. using the look-up table. Using an adder 341, the noise level and the gain A converted to decibels, are subtracted from the sound level, which is outputted from the level detector 32 and converted in decibels to obtain a second difference. The second difference is determined whether it is a negative value by a second sign detector 342. When the second difference is negative, a counter 343 is activated to start counting. Upon a counter value indicating reaching the predetermined time period, a selection signal is asserted to a multiplexer 310 in the gain generator 31 to replace the first difference outputted from the target volume comparator 33 by the negative value of the gain outputted from the decibel converter 340. It should be noted that the negative value in decibels is in fact a reciprocal of a corresponding scalar value. Therefore, after the sound signal determined as a noise has reached the predetermined time period, the gain generator 31 stops amplifying the sound signal determined as a noise, and quickly reduces the gain outputted from the gain generator, thereby preventing the noise from being erroneously amplified.

FIG. 4c and FIG. 4d show detailed block diagrams of the gain generator 31 in FIG. 3c, and the gain generator 31 and the noise detector 34 in FIG. 3d, respectively. Operations of FIG. 4c are similar to those of FIG. 4a, and operations of FIG. 4d are similar to those of FIG. 4b, with the only difference of the timing of applying the gain, and shall be omitted for brevity.

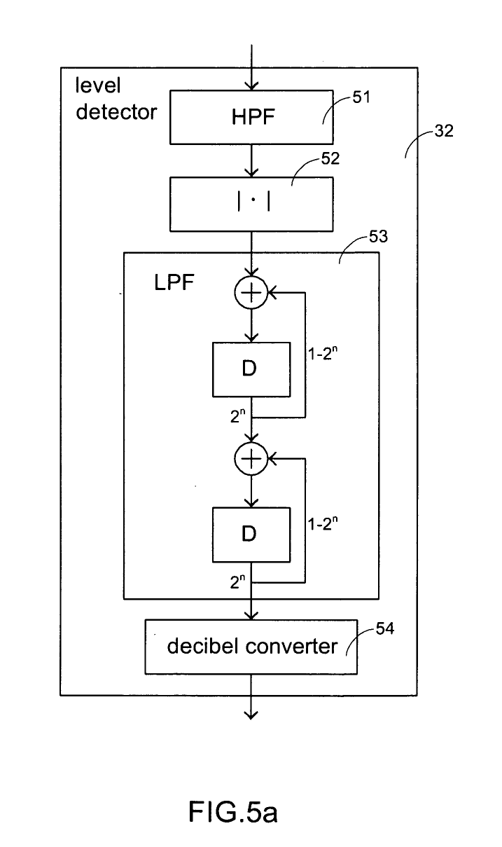

FIG. 5a shows a detailed functional block diagram of the level detector 32. The level detector 32 comprises a high-pass filter (HPF) 51, an absolute value unit 52, a low-pass filter (LPF) 53 and a decibel converter 54. The HPF 51 removes DC components and bass from the auto-gain sound signal, is an optional element and shall be applied based on actual needs. The absolute unit 52 changes negative components of the AC signal in the auto-gain sound signal to positive components, and accumulates the positive components through the LPF 53. LPF 53 exemplifies a second-order LPF, and can be in other types. Accordingly, a sound level associated with the energy or waveform amplitude average of the auto-gain sound signal is obtained and then converted into a sound level in decibels by a decibel converting unit 53, e.g., a look-up table. The absolute value unit 52 may also be implemented using a root-mean-square (RMS) unit, which however has more complex operations that may lead to higher hardware costs. For example, a parameter n of the LPF 53 approximately ranges between −2 to −9. By modifying the parameter n, the frequency response of the LPF 53 can be changed. Referring to FIG. 5b, for the LPF 53, the delay time gets shorter and the cut-off frequency gets higher as n gets larger; vice versa, the delay time gets longer and the cut-off frequency gets lower as n gets smaller. Therefore, the cut-off frequency of the LFP 53 and the delay of the programmable delay 39 is determined by the parameter n.

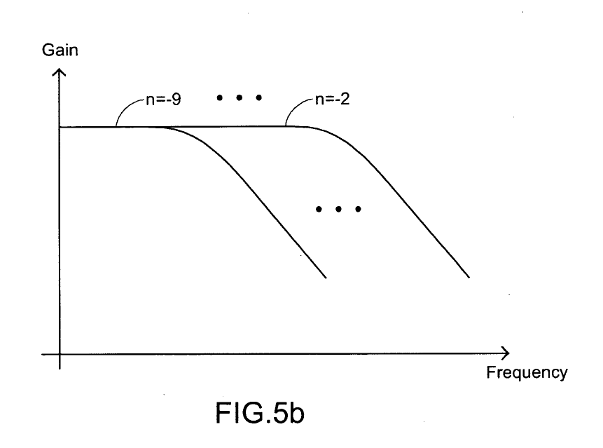

Referring FIG. 6 showing a waveform schematic diagram of the gain A, the original sound signal and the auto-gain sound signal according to one embodiment of the invention, a first response time and a second response time are illustrated. The first response time represents the time needed for the gain A to turn from low to high when the original sound signal is suddenly turned from high to low. Conversely, the second response time represents the time needed for the gain A to turn from high to low when the original sound signal suddenly turns from low to high. Lengths of the two response time are determined by the increment curve and the decrement curve of the gain timing controller 42. The increment curve and the decrement curve may have similar degree of variations. Preferably, the increment curve is provided with more moderate variations compared to the decrement that has more extreme variations, as observed from the diagram, to provide more pleasant hearing effects. That is, within a unit time, the degree that the gain A turns from low to high is smaller than it turns from high to low. Therefore, an original sound signal lower than the target volume is gradually amplified whereas an original sound signal higher than the target volume is rapidly suppressed.

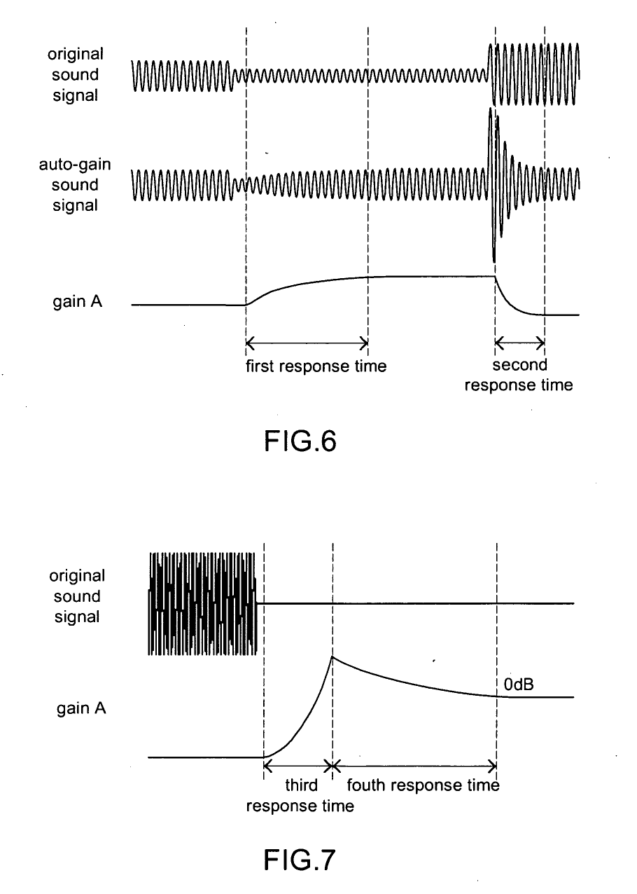

Referring to FIG. 7 showing a waveform schematic diagram of the gain A and the original sound signal upon detecting a noise when operating the apparatus according to one embodiment of the invention. A third response time and a fourth response time are similarly illustrated. The third response time represents the predetermined time period controlled by the counter 343, and the fourth response time represents the time needed by the gain generator 31 to reset the gain to 0 dB. Lengths of both are programmable and adjustable by a user.

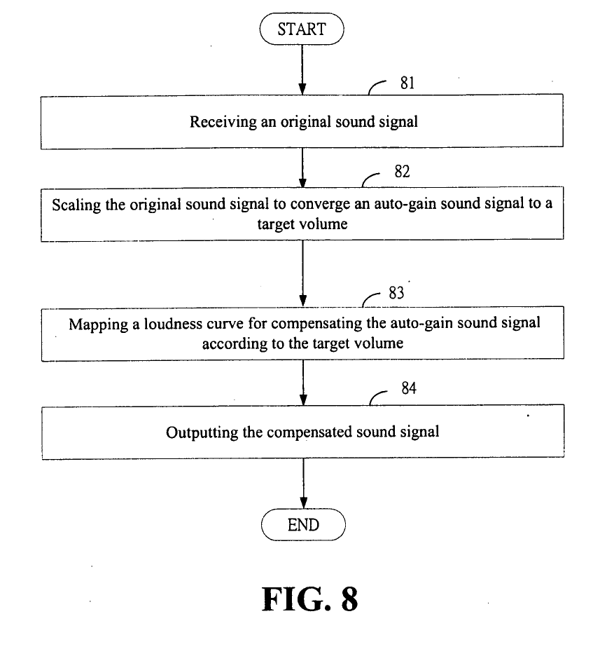

FIG. 8 shows a flowchart of a volume control method according to one embodiment of the invention. The flowchart starts with Step 81 of receiving an original sound signal. In Step 82, according to a target volume, the original sound signal, by reducing or amplifying the energy or waveform amplitude, is adjusted to converge an auto-gain sound signal to the target volume. In Step 83, according to the target volume, a loudness curve is rendered for compensating the auto-gain sound signal. In Step 84, output the compensated sound signal.

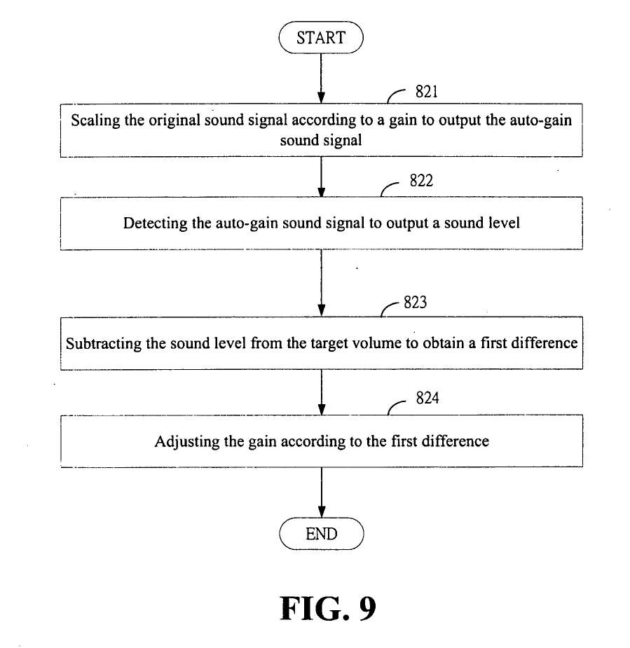

FIG. 9 further illustrates details of Step 82 in FIG. 8. In Step 821, the original sound signal is adjusted according to a gain to output the auto-gain sound signal. In Step 822, the level of the auto-gain sound signal is detected to output a sound level. In Step 823, the sound level is subtracted from the target volume to obtain a first difference. In Step 824, the gain is increased or decreased according to the first difference.

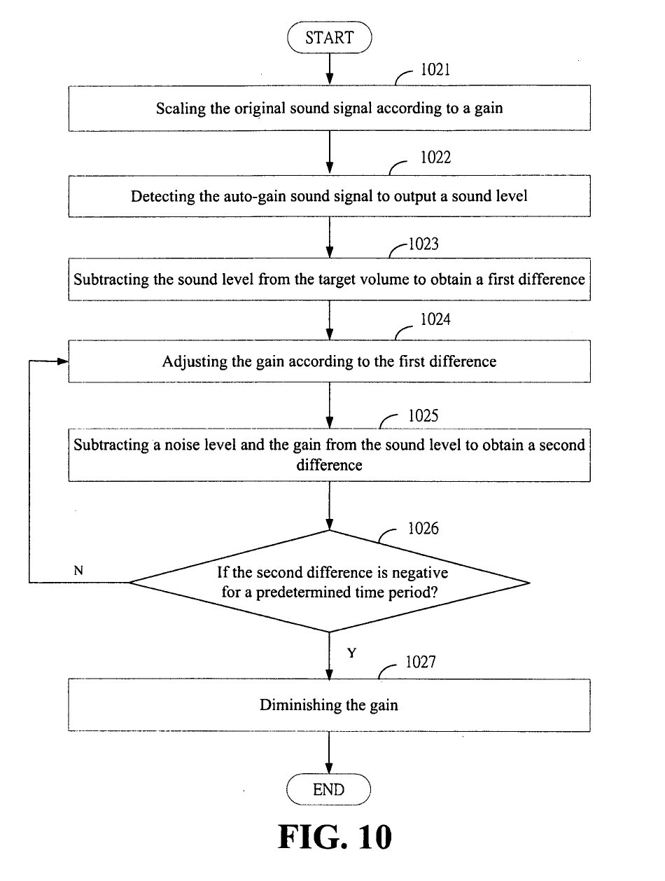

FIG. 10 further illustrates details of Step 82 in FIG. 8. The flow starts with Step 1021, in which the original sound signal is adjusted according to a gain to output an auto-gain signal. In Step 1022, the level of the auto-gain sound signal is detected to output a sound level. In Step 1023, the sound level is subtracted from the target volume to obtain a first difference. In Step 1024, the gain is increased or decreased according to the first difference. In Step 1025, a noise level and the gain are subtracted from the sound level to obtain a second difference. In Step 1026, determine whether the second difference stays negative for a predetermined time period. In Step 1027, if the result from Step 826 is affirmative, the gain is reset to zero. If the result is negative, the flow returns to Step 1024.

From the above embodiments describing the apparatus and method according to the invention, it is clear that the volume control apparatus and method effectively auto-monitor the volume of a television to eliminate disturbances caused by volume variations as well as troubles of manual adjustment. Further, by compensating the auto-gain sound signal with different loudness curves corresponding to the target volume, depreciation in sound quality and dynamic response resulted from suppressing the volume variations is also prevented.

While the invention has been described in terms of what is presently considered to be the most practical and preferred embodiments, it should be understood that the invention needs not to be limited to the above embodiments. On the contrary, it is intended to cover various modifications and similar arrangements included within the spirit and scope of the appended claims which are to be accorded with the broadest interpretation so as to encompass all such modifications and similar structures.

What is claimed is:

1. A volume control apparatus, for adjusting an original sound signal according to a target volume, comprising:
an automatic gain controller, for receiving and adjusting the original sound signal to output an auto-gain sound signal that gradually converges to the target volume; and
an equal loudness controller, coupled to the automatic gain controller, for rendering a loudness curve according to the target volume to compensate the auto-gain sound signal to output a compensated sound signal.

2. The volume control apparatus as claimed in claim 1, wherein the equal loudness controller renders a plurality of loudness curves corresponding to different volumes; and the loudness curves within a predetermined frequency range is varied less than the loudness curves outside the predetermined frequency range.

3. The volume control apparatus as claimed in claim 2, wherein the equal loudness controller is a programmable bi-quadratic impulse response filter, which selects one of the plurality of loudness curves by setting parameters of the programmable bi-quadratic impulse response filter.

4. The volume control apparatus as claimed in claim 1, wherein the automatic gain controller comprises:
a first multiplier, for multiplying the original sound signal with a gain to output the auto-gain sound signal to the equal loudness controller;
a level detector, coupled to the first multiplier, for detecting the outputted auto-gain sound signal and then to output a sound level;
a target volume comparator, coupled to the level detector, for subtracting the sound level from the target volume to obtain a first difference; and
a gain generator, coupled to the target volume comparator and the first multiplier, for generating the gain and adjusting the gain according to the first difference.

5. The volume control apparatus as claimed in claim 4, wherein the gain generator comprises:
a second multiplier, coupled to the target volume comparator, for multiplying the first difference outputted from the target volume comparator with the gain to obtain a first product;
a first sign detector, coupled to the second multiplier, for sending a selection signal in response to a positive/negative sign of the first product;
a gain timing controller, coupled to the first sign detector, for selecting a corresponding increment curve in response to the selection signal;
an adder, coupled to the gain timing controller and the second multiplier, for incrementing the gain; and
a decibel/scalar converter, for converting a unit of the gain into a scalar and outputting the gain in the scalar to the first multiplier.

6. The volume control apparatus as claimed in claim 5, wherein the gain generator further comprises a limiter, which is between the adder and the decibel/scalar converter in order to limit the gain under a predetermined maximum value.

7. The volume control apparatus as claimed in claim 1, wherein the automatic gain controller comprises:
a first multiplier, for multiplying the original sound signal with a gain to output the auto-gain sound signal to the equal loudness controller;
a level detector, coupled to the first multiplier, for detecting the outputted auto-gain sound signal and then to output a sound level;
a target volume comparator, coupled to the level detector, for subtracting the sound level from the target volume to obtain a first difference;
a gain generator, coupled to the target volume comparator and the first multiplier, for generating the gain, and adjusting the gain according to the first difference; and
a noise detector, coupled to the level detector and the gain generator, for obtaining a second difference by subtracting a noise level and the gain from the sound level from the level detector ; wherein, the gain outputted from the gain generator is reset to zero when the second difference stays negative for a predetermined time period.

8. The volume control apparatus as claimed in claim 7, wherein the gain generator comprises:
a multiplexer, coupled to the noise detector and the target volume comparator, controlled by the noise detector to output either the first difference or a reciprocal of the gain;
a second multiplier, coupled to the multiplexer, for multiplying the multiplexer's output with the gain to obtain a first product;
a first sign detector, coupled to the second multiplier, for sending a selection signal in response to a positive or negative sign of the first product;
a gain timing controller, coupled to the first sign detector, for selecting a corresponding increment curve in response to the selection signal;
an adder, coupled to the gain timing controller and the second multiplier, for incrementing the gain; and
a decibel/scalar converter, for converting a unit of the gain into a scalar to be outputted to the first multiplier.

9. The volume control apparatus as claimed in claim 8, wherein the gain generator further comprises a limiter, which is between the adder and the decibel/scalar converter and limits the gain under a predetermined maximum value.

10. The volume control apparatus as claimed in claim 4 or claim 7, wherein the level detector comprises:
a high-pass filter, coupled to the first multiplier, for removing DC components and bass from the auto-gain sound signal;
an absolute value unit, coupled to the high-pass filter, for converting negative components of the auto-gain sound signal to positive components;
a low-pass filter, coupled to the absolute value unit, for obtaining a sound level associated with the auto-gain sound signal; and
a decibel converter, coupled to the low-pass filter and the target volume comparator, for converting the sound level into a unit of decibels using a look-up table and outputting the sound level in decibels to the target volume comparator.

11. The volume control apparatus as claimed in claim 1, wherein the automatic gain controller comprises:
a programmable delay, for delaying the original sound signal with a predetermined delay;
a multiplier, coupled to the programmable delay, for multiplying the delayed original sound signal according to a gain to output the auto-gain sound signal to the equal loudness controller;
a level detector, coupled to the multiplier, for detecting the outputted auto-gain sound signal and then to output a sound level;
a target volume comparator, coupled to the level detector, for subtracting the sound level from the target volume to obtain a first difference; and
a gain generator, coupled to the target volume comparator and the multiplier, for generating the gain, and adjusting the gain according to the first difference.

12. The volume control apparatus as claimed in claim 1, wherein the automatic gain controller comprises:
a programmable delay, for delaying the original sound signal with a predetermined delay;
a multiplier, coupled to the programmable delay, for multiplying the delayed original sound signal according to a gain and then to output the auto-gain sound signal to the equal loudness controller;
a level detector, coupled to the multiplier, for detecting the outputted auto-gain sound signal and then to output a sound level;
a target volume comparator, coupled to the level detector, for subtracting the sound level from the target volume to obtain a first difference;
a gain generator, coupled to the target volume comparator and the multiplier, for generating the gain and adjusting the gain according to the first difference; and
a noise detector, coupled to the level detector and the gain generator, for obtaining a second difference by subtracting a noise level and the gain from the sound level from the level detector; wherein, the gain outputted from the gain generator is reset to zero when the second difference stays negative for a predetermined time period.

13. A volume control method, for adjusting an original sound signal to a target volume, comprising steps of:
receiving the original sound signal;
adjusting the original sound signal according to the target volume to output an auto-gain sound signal that gradually converges to the target volume; and
rendering a loudness curve according to the target volume to compensate the auto-gain sound signal to output a compensated sound signal.

14. The volume control method as claimed in claim 13, wherein the loudness curve is selected from a plurality of loudness curves corresponding to the target volume at different levels; and the loudness curves within a predetermined frequency range is varied less than the loudness curves outside the predetermined frequency range.

15. The volume control method as claimed in claim 13, wherein the step of adjusting the original sound signal according to the target volume comprises steps of:
adjusting the original sound signal according to a gain to output the auto-gain sound signal;
detecting a sound level of the auto-gain sound signal to output the sound level;
subtracting the sound level from the target volume to obtain a first difference; and
adjusting the gain according to the first difference.

16. The volume control method as claimed in claim 15, wherein the step of adjusting the gain according to the first difference comprises steps of:
multiplying the first difference with the gain to obtain a first product;
sending a selection signal in response to a sign of the first product;
selecting a corresponding increment curve in response to the selection signal; and
incrementing the gain.

17. The volume control method as claimed in claim 16, wherein the incremented gain is limited under a maximum value.

18. The volume control method as claimed in claim 13, wherein the step of adjusting the original sound signal according to the target volume comprises steps of:
adjusting the original sound signal according to a gain to output the auto-gain sound signal;
detecting a sound level of the auto-gain sound signal to output the sound level;
subtracting the sound level from the target volume to obtain a first difference;
adjusting the gain according to the first difference; and
subtracting a noise level and the gain from the sound level, to obtain a second difference; wherein, the gain is reset to zero when the second difference stays negative for a predetermined time period.

19. The volume control method as claimed in claim 18, wherein the step of adjusting the gain according to the first difference comprises steps of:
outputting either the first difference or a reciprocal of the gain as a selected output in response to the second difference;
multiplying the selected output with the gain to obtain a first product;
sending a selection signal in response to a sign of the first product;
selecting a corresponding increment curve in response to the selection signal; and
incrementing the gain.

20. The volume control method as claimed in claim 19, wherein the incremented gain is limited under a maximum value.

21. The volume control method as claimed in claim 13, wherein the step of adjusting the original sound signal according to the target volume comprises steps of:
delaying the original sound signal by a predetermined delay;
adjusting the delayed original sound signal according to a gain to output the auto-gain sound signal;
subtracting a sound level from the target volume to obtain a first difference; and
adjusting the gain according to the first difference.

22. The volume control method as claimed in claim 13, wherein the step of adjusting the original sound signal according to the target volume comprises steps of:
delaying the original sound signal by a predetermined delay;
adjusting the delayed original sound signal according to a gain to output the auto-gain sound signal;
subtracting a sound level from the target volume to obtain a first difference;
adjusting the gain according to the first difference; and
subtracting a noise level and the gain from the sound level to obtain a second difference; wherein, the gain is reset to zero when the second difference stays negative for a predetermined time period.
